(19) United States
(12) Patent Application Publication
(10) Pub. No.: US 2025/0133678 A1
(43) Pub. Date: Apr. 24, 2025

(54) MODULAR CONNECTOR FOR AN ELECTRONIC DEVICE

(71) Applicant: HEWLETT PACKARD ENTERPRISE DEVELOPMENT LP, Spring, TX (US)

(72) Inventors: Chih-Wei Chiang, Taipei (TW); Chui Ching Chiu, Taipei (TW); Hsueh Yu Chao, Taipei (TW)

(21) Appl. No.: 18/491,361

(22) Filed: Oct. 20, 2023

(51) Int. Cl. H05K 7/14; H01R 12/72; H01R 43/26

(52) U.S. Cl. CPC H05K 7/1452; H01R 12/722; H01R 43/26; H05K 7/1422

(57) ABSTRACT

An electronic device includes a chassis, a primary system board mounted to the chassis, first and second connectors, and a set of support members coupled to the chassis. The first connector is directly mounted and electrically connected to the primary system board, and includes first and second support walls, and a first pin protruding from the first support wall. The second connector includes a cable electrically connected to the primary system board, and includes third and fourth support walls, a first hole formed in the third support wall, and a second hole formed in the fourth support wall. A support member of the set of support members includes a second pin. The first pin protrudes into the first hole to couple the second connector to the first connector, and the second pin protrudes into the second hole to further couple the second connector to the first support member.

### BACKGROUND

An electronic device such as a computer, a networking device, or the like may include a primary system board (e.g., a motherboard or a host platform module) having electronic components such as central processor units, resistors, capacitors, or the like to provide some basic function. To expand the functionality of the electronic device, additional electronic modules such as an integrated circuit module, a storage module, or the like may have to be detachably connected to the primary system board. Therefore, the primary system board may include connectors that can detachably connect with complementary connectors of the electronic module, thereby establishing an electrical connection between the electronic modules and the electronic device and expanding the functionality of the electronic device.

### BRIEF DESCRIPTION OF THE DRAWINGS

Various examples will be described below with reference to the following figures.

FIG. 1A illustrates a block diagram of a modular connector system to assemble a connector assembly for an electronic device according to an example of the present disclosure.

FIG. 1B illustrates a block diagram of an example connector assembly assembled from the modular connector system of FIG. 1A according to an example of the present disclosure.

FIG. 1C illustrates a block diagram of another example connector assembly assembled from the modular connector system of FIG. 1A according to an example of the present disclosure.

FIG. 2A illustrates a perspective view of a first connector having a first configuration according to an example of the present disclosure.

FIG. 2B illustrates a perspective view of a second connector having a second configuration according to an example of the present disclosure.

FIG. 2C illustrates a perspective view of a third connector having a first configuration according to an example of the present disclosure.

FIG. 3A illustrates a perspective view of a first support member according to an example of the present disclosure.

FIG. 3B illustrates a perspective view of a second support member according to an example of the present disclosure.

FIG. 3C illustrates a perspective view of a third support member according to an example of the present disclosure.

FIG. 4 illustrates a perspective view of a primary system board connected to the first connector of FIG. 2A according to an example of the present disclosure.

FIG. 5 illustrates a perspective view of a primary circuit board (PCB) electrically coupled to a cable according to an example of the present disclosure.

FIG. 6A illustrates an electronic module having a large form factor according to an example of the present disclosure.

FIG. 6B illustrates another electronic module having a small form factor according to an example of the present disclosure.

FIG. 7A illustrates a perspective view of the primary system board of FIG. 4 connected to a connector assembly having the first connector of FIG. 2A, the second connector of FIG. 2B, the PCB of FIG. 5, the first support member of FIG. 3A, and the second support member of FIG. 3B according to an example of the present disclosure.

FIG. 7B illustrates a perspective view of an electronic device having a chassis and the primary system board of FIG. 4, electrically connected to an electronic module of FIG. 6A via the connector assembly of FIG. 7A according to an example of the present disclosure.

FIG. 8A illustrates a perspective view of the primary system board of FIG. 4 connected to another connector assembly having the first connector of FIG. 2A, the third connector of FIG. 2C, the first support member of FIG. 3A, the PCB of FIG. 5, the second support member of FIG. 3B, and a third support member of FIG. 3C according to an example of the present disclosure.

FIG. 8B illustrates a perspective view of another electronic device having the primary system board of FIG. 8A, electrically connected to two electronic modules of FIG. 6B via the connector assembly of FIG. 8A according to an example of the present disclosure.

FIG. 9 is a flowchart depicting a method of installing a connector assembly to a primary system board of an electronic device according to one example of the present disclosure.

### DETAILED DESCRIPTION

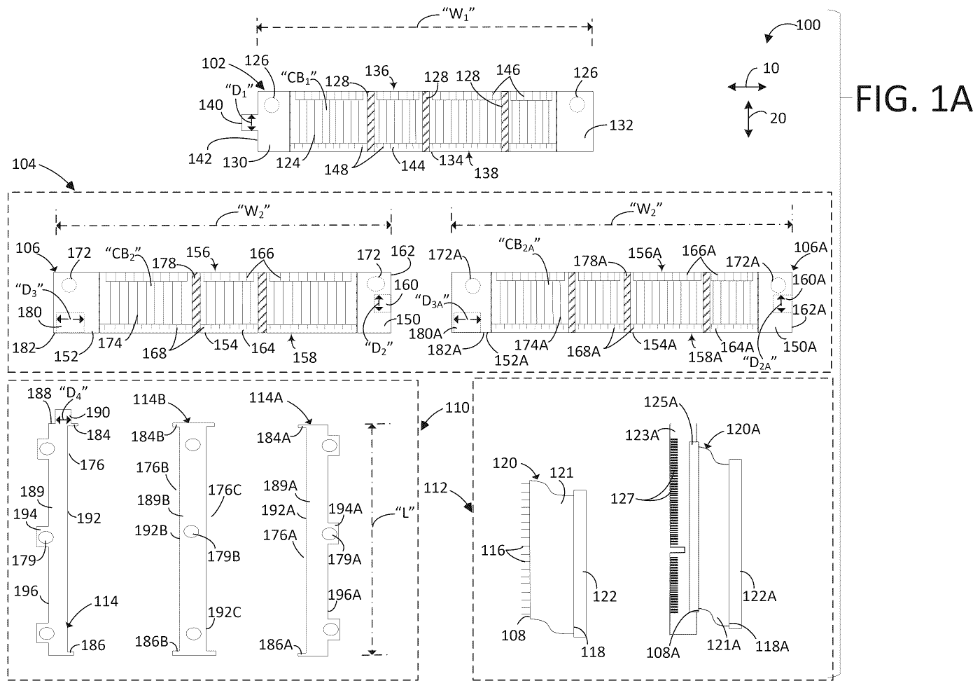

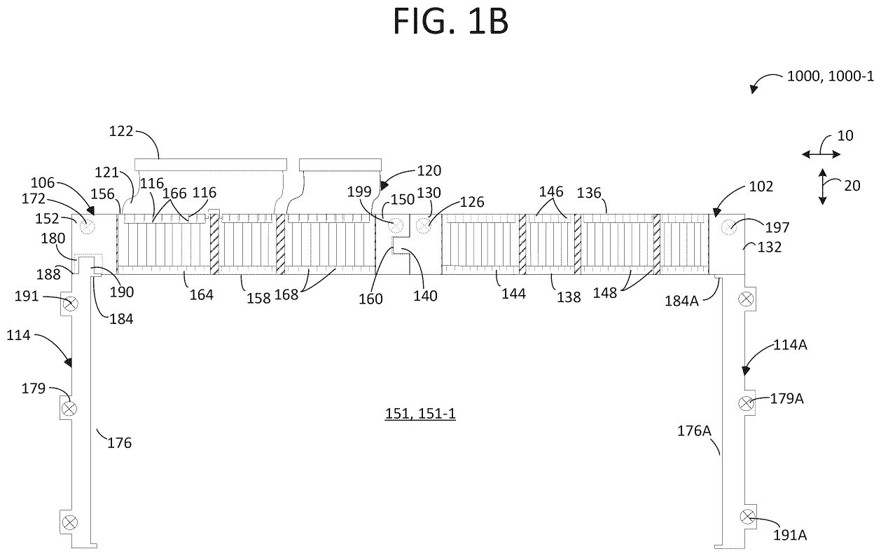

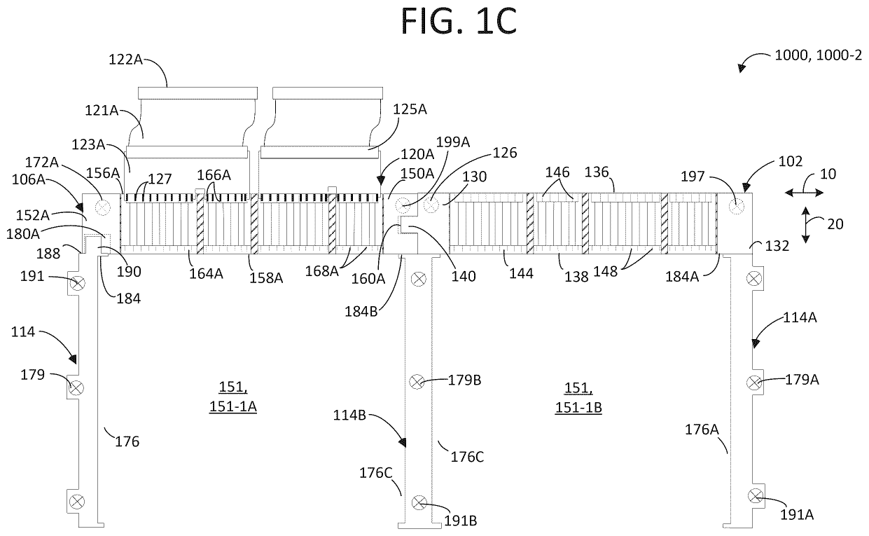

The following detailed description refers to the accompanying drawings. For purposes of explanation, certain examples are described with reference to the components illustrated in FIGS. 1-9. The functionality of the illustrated components may overlap, however, and may be present in a fewer or greater number of elements and components. Moreover, the disclosed examples may be implemented in various environments and are not limited to the illustrated examples. Wherever possible, the same reference numbers are used in the drawings and the following description to refer to the same or similar parts. It is to be expressly understood, however, that the drawings are for the purpose of illustration and description only. While several examples are described in this document, modifications, adaptations, and other implementations are possible. Accordingly, the following detailed description does not limit the disclosed examples. Instead, the proper scope of the disclosed examples may be defined by the appended claims.

A connector and support members defining a bay may facilitate inclusion of an electronic module such as an open compute program (OCP) module in an electronic device e.g., a server to expand the functionality of the electronic device. Accordingly, in an electronic device that is configured to receive the electronic module, a primary system board (e.g., a motherboard or a host platform module) of the electronic device has the connector pre-arranged at the back edge thereof to mate with a complementary connector of the electronic module as the electronic module is slid into the bay of the electronic device. Conventionally, this connector is a receptacle-style connector that is fixedly attached to the edge of the primary system board and electrically connected to the primary system board via edge-style (e.g., gold-finger style) contacts on the primary system board. Accordingly, as the electronic module is inserted into the bay, the complementary connector may be removably coupled to the connector, thus electrically connecting the electronic module to the primary system board via the connector. Therefore, when the electronic module is removably coupled to the connector, electrical signals from the electronic module may be transferred to the primary system board via the connector.

The electronic module may have different form factors such as a first electronic module having a large form factor, and a second electronic module having a small form factor. In such examples, the first electronic module may have a first width, and include a set of complementary connectors (e.g., a first complementary connector and a second complementary connector), and the second electronic module may have a second width, and include a complementary connector (e.g., a third complementary connector), where the first width is greater than the second width, and each of the first and third complementary connectors has a common profile (a first profile) and the second complementary connector has a second profile different from the first profile. Therefore, a connector assembly that may be used to facilitate the inclusion of at least one electronic module in the electronic device may also need to have different configurations, e.g., a first connector assembly having a first configuration associated with the large form factor of the first electronic module, and a second connector assembly having a second configuration associated with the small form factor of the second electronic module to enable the connector to removably couple with the at least one electronic module having a corresponding form factor. In particular, the first connector assembly may require a set of connectors such as a first connector having a profile that is compatible with the first profile of the first complementary connector and a second connector having another profile that is compatible with the second profile of the second complementary connector so as to enable the first connector assembly to removably couple with the first electronic module. Similarly, the second connector assembly may also require a set of connectors such as a third connector and a fourth connector, each having a profile that is compatible with the second electronic module so as to enable the second electronic module to removably couple with any one of the third or fourth connectors. It may be noted herein that the first connector of the first connector assembly and each of the third and fourth connectors of the second connector assembly have the common profile. Accordingly, when the electronic device including an electronic module having a large form factor needs to be switched over to new electronic modules, each having a small form factor, then a pre-installed connector assembly configured to removably couple with the electronic module having the large form factor has to be replaced with a new connector assembly to allow the new electronic modules to removably couple with the new connector assembly. For example, if the pre-installed first connector assembly having the first configuration is installed in the electronic device to removably couple with the first electronic module, and later there is a requirement to replace the first electronic module with the second electronic modules, then the pre-installed first connector assembly may also have to be replaced with the second connector assembly having the second configuration to allow inclusion of the second electronic modules in the electronic device. Hence, replacing the electronic module with the new electronic modules or vice versa may be cumbersome, time consuming, expensive, and depend on the availability of inventory of such new compatible connector assembly. In addition, multiple different types of connector assemblies may need to be produced, and this may result in additional SKUs being needed and different inventory to be maintained, which can in turn increase costs.

Additionally, since the connector is fixedly attached to the edge of the primary system board, any tolerance stack-up in the connector may lead to a misaligned connector, which results in the electronic module been unable to removably couple with such misaligned connector. Therefore, the electronic device may be forced to undergo unavoidable shutdown to fix alignment problems associated with the misaligned connector.

A technical solution to the aforementioned problems may include providing a connector assembly that is reconfigurable into multiple configurations that are compatible with multiple different form factors of electronic modules. More specifically, a reconfigurable connector assembly includes a first connector (e.g., a common connector), and a second connector (e.g., a replaceable connector) removably coupled to the first connector, with the second connector being one of a set of multiple different second connectors which are interchangeably connectable to the first connector. Thus, the connector assembly can be reconfigured to have different configurations (e.g., to accommodate different electronic modules) by disconnecting the currently connected second connector from the first connector, and then connecting another one of the second connectors to the first connector. Consequently, reconfiguring the connector assembly does not require replacing the first connector (which has a common profile to all configurations of the electronic module), and thus during a process of reconfiguring the connector assembly, the first connector can remain connected to a primary system board, and only the second connector may be changed depending on a profile of the corresponding complementary connector of the electronic module. Therefore, it can be much easier to replace an electronic module in the electronic device that utilizes the example replaceable connector assembly disclosed herein.

In examples disclosed herein, a given configuration of the connector assembly that is compatible with a given form factor of the electronic module may be formed by i) selecting the second connector, out of the multiple interchangeable second connectors, that corresponds to (e.g., has a profile commensurate with) the given complementary connector of the electronic module and ii) assembling such selected second connector to the first connector. Moreover, the connector assembly can be changed to accommodate different form factors of the electronic modules by changing which second connector is used, but without needing to replace an entire connector assembly. For example, a first connector which has the common profile that is compatible with a first profile of a first complementary connector of a first electronic module having a large form factor and a third profile of a third complementary connector of a second electronic module having a small form factor may be retained in a connector assembly. In such examples, a second connector having a profile that is compatible with a second profile of a second complementary connector of the first electronic module may be selected, and removably coupled to the first connector to form a first connector assembly so as to enable the first connector assembly to removably couple with the first electronic module having the large form factor. Similarly, a third connector having a profile that is compatible with the third complementary connector of the second electronic module may be selected, and removably coupled to the first connector to form a second connector assembly so as to enable the second connector assembly to removably couple with two second electronic modules, each having the small form factor. More specifically, the first connector may be retained as-is and the second and third connectors may be interchangeably selected depending on the compatibility with the electronic module, and removably coupled to the first connector to form the first connector assembly or the second connector assembly. Since the first connector is retained and only the second connectors are interchanged to assemble the new connector assembly that is compatible with the electronic module, such new connector assembly provides flexibility, upgradability, serviceability, and benefits from supply chain in terms of reducing number of ready-made connector assembly needed in the inventory.

In some cases, the first connector may be a 4C+ connector and the second connector may be one of a 4C connector or a 4C+ connector. In some examples, the first and second complementary connectors of the first electronic module having the large form factor (LFF) may be compatible with the 4C+ and 4C connectors, respectively, of the first connector assembly. Similarly, each of the first and third complementary connectors of the second electronic module having the small form factor (SFF) may be compatible with the 4C+ connectors of the second connector assembly. In one or more examples, each of the first and second electronic modules may be an open compute program (OCP) module. In some examples, the OCP module may be a modular network module having multiple network interface ports that can be configured to support various networking protocols such as Ethernet, Modbus TCP, PROFINET, IEC 61850, or the like.

In some examples, when a selected second connector is connected to the first connector to form a desired connector assembly, the second connector is not fixedly connected to the primary system board, instead the second connector includes a flexible cabling that is electrically connected to the primary system board. In other words, the second connector is not electrically connected to edge-style contacts on the primary system board but is instead connected to the primary system board via the flexible cabling. Accordingly, since the second connector with the flexible cabling is not fixedly attached directly to the primary system board, the second connector is secured in place by pinned connections to the first connector (which is fixedly attached to the primary system board) and to support members that guide and support the electronic module. Thus, the pinned connections allow the second connector to float or move within a limited range relative to the first connector, which allows the second connector to be aligned with the electronic module in view of tolerance stack up. In addition, since the second connector is not fixed to the primary system board, it can be relatively easily removed and replaced with a different version of the second connector. This can allow different combinations of the electronic modules that have different connector requirements to be accommodated. For example, if a configuration with two SFF OCP modules are desired, a second connector (e.g., a floating connector compatible with the OCP 4C+ connector) may be used together with a first connector (e.g., a fixed connector compatible with the OCP 4C+ connector). If a different configuration including one LFF OCP module is desired, another second connector (e.g., another floating connector compatible with the OCP 4C connector) may be used (instead of the floating connector compatible with the OCP 4C+ connector) together with the same first connector (e.g., the fixed connector compatible with OCP 4C+ connector).

In some examples, an electronic device includes a chassis, a primary system board, a connector assembly including a first connector, a second connector, and a set of support members. The primary system board is mounted to the chassis and includes processing circuitry. The first connector is directly mounted and electrically connected to the primary system board. The first connector includes a first support wall, a second support wall, and a first pin protruding from a side face of the first support wall and extending along a first direction. The second connector includes a cable electrically connected to the primary system board, a third support wall, a fourth support wall, a first hole formed at a side face of the third support wall, and a second hole formed at a rear face of the fourth support wall. The first pin protrudes at least partially into the first hole to removably couple the second connector to the first connector. The set of support members is coupled to the chassis and defines at least one bay, where a first support member of the set of support members includes a front face and a second pin protruding from the front face and extending along a second direction perpendicular to the first direction. The second pin protrudes into the second hole to removably couple the second connector to the first support member. In some examples, at least one electronic module is insertable into the at least one bay to detachably couple with at least one of the first and second connectors to electrically connect the at least one electronic module to the primary system board via the first and second connectors. In such examples, the first and second holes allow the second connector to move along the first direction relative to the first and second pins to allow the second connector to be aligned with the at least one electronic module.

Referring to the Figures, FIG. 1A depicts a block diagram of a modular connector system 100 for assembling a connector assembly 1000 of an electronic device. FIGS. 1B and 1C illustrate two example connector assemblies such as a first connector assembly 1000-1 and a second connector assembly 1000-2, each assembled from the modular connector system 100. It should be understood that FIGS. 1A-1C are not intended to illustrate specific shapes, dimensions, or other structural details accurately or to scale, and that implementations of the modular connector system 100 may have different numbers and arrangements of the illustrated components and may also include other parts that are not illustrated. The modular connector system 100 may function as an inventory of components that may be required to assemble the connector assembly 1000. In some examples, the modular connector system 100 includes components such as a fixed connector (e.g., a first connector 102) and a set of mutually different floating connectors 104 that is interchangeably and removably connectable to the first connector 102. The set of floating connectors 104 may include at least a second connector 106 and a third connector 106A.

One of the second or third connectors 106, 106A is removably coupled to the first connector 102 to form the connector assembly 1000, with the connector assembly 1000 being capable of taking on multiple different configurations depending on which one of the second or third connectors 106, 106A is removably coupled to the first connector 102. For example, FIGS. 1B and 1C illustrate two example configurations of the connector assembly 1000, i.e., a first configuration in the form of a first connector assembly 1000-1 which includes the second connector 106 removably coupled to the first connector 102, and a second configuration in the form of a second connector assembly 1000-2 including the third connector 106A removably coupled to the first connector 102. The connector assembly 1000 is also capable of reconfiguration between these different configurations. For example, the connector assembly 1000 can be reconfigured from the configuration of the first connector assembly 1000-1 to the configuration of the second connector assembly 1000-2 by removing the second connector 106 and replacing it with the third connector 106A or vice versa. Below, the description will focus on the first and second connector assemblies 1000-1 and 1000-2 as two illustrative examples, but it should be understood that the connector assembly 1000 may be capable of additional configurations, such as those formed by using other connectors from the set of floating connectors 104. In some examples, each connector among the first and third connectors is a 4C+ connector and the second connector is a 4C connector. Additional details of these components are described in greater detail below.

The first connector 102 includes a first support wall 130, a second support wall 132, a first hollow body portion 134 defined between a first side 136 and a second side 138 of the first connector 102. The first hollow body portion 134 includes a pair of first peripheral end portions (not labeled) interconnected with the first and second support walls 130, 132. The first connector 102 further includes a first pin 140 protruding from a side face 142 of the first support wall 130 and extending along a first direction 10. The first pin 140 has a diameter “D₁”. Further, the first connector 102 includes a set of first contacts 146 on the first side 136 and a first receptacle 144 at the second side 138, where the first receptacle 144 includes a set of second contacts 148. In some examples, each set of the first and second contacts 146, 148 may be conductive spring fingers. The set of first and second contacts 146, 148 may be interconnected to each other via first internal conductors 124 extending along the first hollow body portion 134. In some examples, the first side 136 of the first connector 102 may be mounted to an edge of a primary system board (not shown). For example, the set of first contacts 146 may be configured to clasp onto the edge of the primary system board. Accordingly, the set of first contacts 146 at the first side 136 may be configured to electrically connect to a first edge connector (not shown) of the primary system board. Similarly, the second side 138 of the first connector 102 having the first receptacle 144 may be configured to receive a second edge connector (or a complementary connector) of one of at least one electronic module (not shown) and the set of second contacts 148 may be configured to clasp onto the second edge connector of the at least one electronic module. Accordingly, the set of second contacts 148 at the second side 138 may be configured to electrically connect with the second edge connector of the at least one electronic module. Further, the first connector 102 includes a plurality of first mounting holes 126 disposed on the first support wall 130 and the second support wall 132. In some examples, the first connector 102 may have a first profile. For example, the first profile of the first connector 102 is defined by a four number of connector bays “CB₁” separated from each other by three support elements 128. Further, the first connector 102 has a first width “W₁” extending along the first direction “10”. In some examples, the first connector 102 is a 4C+ connector.

As noted above, the modular connector system 100 includes a set of floating connectors 104. Two example floating connectors, i.e., the second connector 106 and the third connector 106A are described below for ease of illustration, but in examples additional floating connectors may be included in the set of floating connectors 104. In some examples, each of the second and third connectors 106, 106A has a same second width “W₂” extending along the first direction “10”.

In some examples, the second connector 106 includes a third support wall 150, a fourth support wall 152, a second hollow body portion 154 defined between a first side 156 and a second side 158 of the second connector 106. The second hollow body portion 154 includes a pair of second peripheral end portions (not labeled) interconnected with the third and fourth support walls 150, 152. The second connector 106 further includes a first hole 160 formed at a side face 162 of the third support wall 150, and a second hole 180 formed at a rear face 182 of the fourth support wall 152. The first hole 160 extends inwards along the first direction 10 in the third support wall 150 and the second hole 180 extends inwards along a second direction 20 opposite to the first direction 10, in the fourth support wall 152. The first hole 160 has another diameter “D₂” equal to the diameter “D₁” of the first pin 140. The second hole 180 has a first diameter “D₃”. In some examples, the first pin 140 of the first connector 102 may be configured to protrude at least partially into the first hole 160 to removably couple the second connector 106 to the first connector 102. Further, the second connector 106 includes a set of third contacts 166 on the first side 156 and a second receptacle 164 at the second side 158, where the second receptacle 164 includes a set of fourth contacts 168. In some examples, each set of the third and fourth contacts 166, 168 may be conductive spring fingers. In some other examples, the set of third contacts 166 may be a conductive strip. The third and fourth sets of contacts 166, 168 may be interconnected via second internal conductors 174 extending along the second hollow body portion 154. In some examples, the first side 156 of the second connector 106 may be coupled to one of a cable 121 of the first cable member 120 or a cable 121A of the second cable member 120A, and the second side 158 of the second connector 106 having the second receptacle 164 may be configured to receive a third edge connector (or another complementary connector, not shown) of one of the at least one electronic module. For example, the set of third contacts 166 may be either configured to clasp onto a fourth edge connector 127 of a printed circuit board (PCB 123A) or directly soldered to a set of fifth contacts 116 of the cable 121. Similarly, the set of fourth contacts 168 may be configured to clasp onto the third edge connector of the at least one electronic module. Further, the second connector 106 includes a plurality of second mounting holes 172 disposed on the third support wall 150 and the fourth support wall 152. In some examples the second connector 106 may have a second profile. For example, the second profile of the second connector 106 is defined by a three number of connector bays “CB₂” separated from each other by two support elements 178. In some examples, the second connector 106 is a 4C connector.

In some examples, the third connector 106A includes a third support wall 150A, a fourth support wall 152A, a second hollow body portion 154A defined between a first side 156A and a second side 158A of the third connector 106A. The second hollow body portion 154A includes a pair of second peripheral end portions (not labeled) interconnected with the third and fourth support walls 150A, 152A. The third connector 106A further includes a first hole 160A (also referred to as a third hole) formed at a side face 162A of the third support wall 150A, and a second hole 180A (also referred to as a fourth hole) formed at a rear face 182A of the fourth support wall 152A. The first hole 160A extends inwards along the first direction 10 in the third support wall 150A and the second hole 180A extends inwards along a second direction 20 in the fourth support wall 152A. The first hole 160A has another diameter “D_{2A}” equal to the diameter “D₁” of the first pin 140. The second hole 180A has a first diameter “D_{3A}”. In some examples, the first pin 140 of the first connector 102 may be configured to protrude at least partially into the first hole 160A to removably couple the third connector 106A to the first connector 102. Further, the third connector 106A includes a set of third contacts 166A on the first side 156A and a second receptacle 164A at the second side 158A, where the second receptacle 164A includes a set of fourth contacts 168A. In some examples, each set of the third and fourth contacts 166A, 168A may be conductive spring fingers. In some other examples, the set of third contacts 166A may be a conductive strip. The set of third and fourth contacts 166A, 168A may be interconnected via second internal conductors 174A extending along the second hollow body portion 154A. In some examples, the first side 156A of the third connector 106A may be coupled to a cable 121 of the first cable member 120 or to the cable 121A of the second cable member 120A and the second side 158A of the third connector 106A having the second receptacle 164A may be configured to receive a third edge connector (another complementary connector, not shown) of one of the at least one electronic module. For example, the set of third contacts 166A may be either configured to clasp onto the fourth edge connector 127 of the PCB 123A or directly soldered to the set of fifth contacts 116 of the cable 121. Similarly, the set of fourth contacts 168A may be configured to clasp onto the third edge connector of the at least one electronic module. Further, the third connector 106A includes a plurality of second mounting holes 172A disposed on the third support wall 150A and the fourth support wall 152A. In some examples the third connector 106A may have a third profile. For example, the third profile of the third connector 106A is defined by a four number of connector bays “CB_{2A}” separated from each other by three support elements 178A. It may be noted herein that the third profile may be substantially similar to the first profile of the first connector 102. In particular, the first hollow body portion 134 of the first connector 102 is similar to the second hollow body portion 154A of the third connector 106A. Further, the first and second support walls 150, 152 of the second connector 106 are similar to the first and second support walls 150A, 152B of the third connector 106A. In some examples, the third connector 106A is a 4C+ connector.

The set of support members 110 includes a first support member 114, a second support member 114A, and a third support member 114C. The set of support members 110 may be coupled to a chassis (not shown) of the electronic device to define at least one bay 151 for receiving the at least one electronic module. In some examples, the first and second support members 114, 114A may be selected from the set of support members 110 and disposed spaced apart from each other and coupled to the chassis to define a first bay 151-1 configured to receive the at least one electronic module (e.g., a first electronic module) having a large form factor (LFF). In some other examples, the first, second, and third support members 114, 114A, 114B may be selected from the set of support members 110 and disposed spaced apart from each other and coupled to the chassis to define a second bay 151-1A configured to receive the at least one electronic module e.g., a second electronic module having a small form factor (SFF), and a third bay 151-1B configured to receive the at least one electronic module e.g., a third electronic module having the SFF.

The first support member 114 includes a front face 188 defined at a first end 184 of the first support member 114 and a second pin 190 protruding outwards from the front face 188. The second pin 190 extends along a second direction 20 perpendicular to the first direction 10. The second pin 190 may protrude into one of the second holes 180, 180A to removably couple a second connector 106 or a third connector 106A to the first support member 114. The second pin 190 has a second diameter “D₄” smaller than the first diameter “D₃” of the second hole 180 in the second connector 106. Similarly, the second diameter “D₄” of the second pin 190 is also smaller than the first diameter “D_{3A}” of the second hole 180A in the third connector 106A. In some examples, the second pin 190 having the second diameter “D₄” smaller than the first diameter of each of the first hole “D₃”, “D_{3A}” may allow the corresponding second connector 106, 106A to move along the first direction 10. The first support member 114 includes a body portion 189 defined between the first end 184 and a second end 186 of the first support member 114, a first guide rail 176 formed between the first and second ends 184, 186, and a plurality of first fastener holes 179. In some examples, the first guide rail 176 is defined along an inner side 192 of the first support member 114. In some examples, each of the plurality of first fastener holes 179 may be formed on a corresponding flange of a plurality of flanges 194 disposed on an outer side 196 of the body portion 189. The first support member 114 has a length “L” extending between the first and second ends 184, 186.

The second support member 114A includes a body portion 189A defined between a first end 184A and a second end 186A of the second support member 114A, a second guide rail 176A formed between the first and second ends 184A, 186A, and a plurality of second fastener holes 179A. In some examples, the second guide rail 176A is formed along an inner side 192A of the second support member 114A. In some examples, each of the plurality of second fastener holes 179A may be formed on a corresponding flange of a plurality of flanges 194A disposed on outer side 196A of the body portion 189A. The second support member 114A has a length “L” extending between the first and second ends 184A, 186A.

The third support member 114B includes a body portion 189B defined between a first end 184B and a second end 186B of the third support member 114B. The third support member 114B further includes a third guide rail 176B formed between the first and second ends 184A, 186A on a first side 192B of the third support member 114B, and a fourth guide rail 176C formed between the first and second ends 184A, 186A on a second side 192C opposite to the first side 192B of the third support member 114B. In other words, each of the third and fourth guide rails 176B, 176C are formed on a corresponding side of the third support member 114B. Further, the third support member 114B includes a plurality of third fastener holes 179B, where each of the plurality of third fastener holes 179B may be formed on the body portion 189B. The third support member 114B has a length “L” extending between the first and second ends 184B, 186B.

The set of cable assemblies 112 includes a first cable member 120 and a second cable member 120A. One of the first cable member 120 or the second cable member 120A may be coupled to the first side 156 of the second connector 106 and to a surface mount connector (not shown) of the printed system board. Similarly, one of the first cable member 120 or the second cable member 120A may be coupled to the first side 156A of the third connector 106A and to the surface mount connector (not shown) of the printed system board. Thus, the second connector 106 or the third connector 106A is not fixedly connected to the primary system board, instead, the second connector 106 or the third connector 106A includes the flexible first and second cable members 120, 120A, respectively, that is electrically connected to the primary system board. In other words, the second connector 106 or the third connector 106A is not electrically connected to edge-style contacts on the primary system board but is instead connected to the primary system board via the flexible first and second cable members 120, 120A.

The first cable member 120 includes a cable 121 and a surface connector 122. The cable 121 has a first end 108 and a second end 118. The first end 108 of the cable 121 includes a set of fifth contacts 116. In such examples, the set of fifth contacts 116 can be soldered to the set of third contacts 166 of the second connector 106 or to the set of third contacts 166A of the third connector 106A. Further, the second end 118 of the cable 121 may be coupled to the surface connector 122. In such examples, the surface connector 122 may be configured to mount to a surface mount connector (not shown) of the printed system board.

The second cable member 120A includes a cable 121A, a printed circuit board (PCB 123A), a first surface connector 122A, and a second surface connector 125A. The cable 121A includes a first end 108A and a second end 118A. The first end 108A of the cable 121A is coupled to the second surface connector 125A and the second end 118A of the cable 121A is coupled to the first surface connector 122A. In such examples, the second surface connector 125A may be configured to mount to a second end (not labeled) of the PCB 123A and the first surface connector 122A may be configured to mount to a surface mount connector (not shown) of the printed system board. The PCB 123A includes a fourth edge connector 127 disposed at its first end (not labeled), which may be configured to couple to the set of third contacts 166 of the second connector 106 or to the set of third contacts 166A of the third connector 106A.

As discussed herein, the first connector 102 may be configured to directly mount and electrically connect to the primary system board. Further, the second and third connectors 106, 106A are configured to be interchangeably and removably connectable to the first connector 102 to assemble the connector assembly 1000.

In some examples, the second connector 106 is selected from the modular connector system 100 and removably coupled to the first connector 102 to form a first connector assembly 1000-1. In particular, the third support wall 150 of the second connector 106 is placed adjacent to the first support wall 130 of the first connector 102 such that the first pin 140 of the first connector 102 protrudes at least partially into the first hole 160 of the second connector 106 to removably couple the second connector 106 to the first connector 102. Further, the front face 188 of the first support member 114 is disposed adjacent to the fourth support wall 152 of the second connector 106 such that the second pin 190 of the first support member 114 protrudes into the second hole 180 of the second connector 106 to removably couple the second connector 106 to the first support member 114. Since the first diameter “D₃” of the second hole 180 is greater than the second diameter “D₄” of the second pin 190, the second connector 106 is allowed to move along the first direction 10 relative to the first connector 102, which allows the second connector 106 to be aligned with the electronic module in view of tolerance stack up. In other words, the first and second holes 160, 180 allow the second connector 106 to move along the first direction 10 relative to the first and second pins 140, 190. The second support member 114A is disposed spaced apart from the first support member 114 such that a front face of the first end 184A in the second support member 114A contacts the second support wall 132 and defines at least one bay 151 e.g., a first bay 151-1 between the first and second support members 114, 114A and the first and second connectors 102, 106. Further, each of the first and second support members 114, 114A may be coupled to the chassis. In particular, a plurality of first fasteners 191 may extend into the plurality of first fastener holes 179 in the first support member 114, and into a plurality of first holes (not shown) in the chassis to couple the first support member 114 to the chassis. Similarly, a plurality of second fasteners 191A may extend into the plurality of second fastener holes 179A in the second support member 114A and into a plurality of second holes (not shown) in the chassis to couple the second support member 114A to the chassis. In some examples, at least one electronic module e.g., a first electronic module having a large form factor is insertable into the first bay 151-1 to detachably couple with the first and second connectors 102, 106 and electrically connect the first electronic module to the primary system board via the first and second connectors 102, 106. For example, the first electronic module slidingly may engage with the first and second guide rails 176, 176A to move inside the first bay 151-1 and detachably couple with the first and second connectors 102, 106.

In some examples, the first side 136 of the first connector 102 is configured to mount to an edge of the first edge connector (not shown) in the primary system board. More particularly, the set of first contacts 146 at the first side 136 of the first connector 102 may be configured to clasp onto the edge of the first edge connector and electrically connect with the first edge connector of the primary system board. Further, the first receptacle 144 at the second side 138 of the first connector 102 is configured to receive a complementary connector e.g., a second edge connector of the first electronic module. More particularly, the set of second contacts 148 at the second side 138 of the first connector 102 may be configured to clasp onto the second edge connector of the first electronic module and electrically connect with the second edge connector of the first electronic module.

Further, the first side 156 of the second connector 106 is coupled to the first cable member 120 e.g., the cable 121, and the second receptacle 164 at the second side 158 of the second connector 106 is configured to receive another complementary connector e.g., a third edge connector of the first electronic module. In particular, the set of third contacts 166 at the first side 156 of the second connector 106 is soldered to the set of fifth contacts 116 of the cable 121 to electrically connect the cable 121 with the surface connector 122. In such examples, the surface connector 122 may be configured to mount to a surface mount connector of the printed system board. Further, the second receptacle 164 at the second side 158 of the second connector 106 is configured to receive the third edge connector of the first electronic module. More particularly, the set of fourth contacts 168 at the second side 158 of the second connector 106 may be configured to clasp onto the third edge connector of the first electronic module and electrically connect with the third edge connector of the first electronic module.

In some examples, the first connector 102 may be coupled to the printed system board by extending a plurality of first fasteners 197 through the plurality of first mounting holes 126 in the first connector 102. Similarly, the second connector 106 may be optionally coupled to the printed system board, after the first electronic module is clasped to the first and second connectors 102, 106 by extending a plurality of second fasteners 199 through the plurality of first mounting holes 172 in the second connector 106.

Accordingly, in some examples, in an installed state of the first connector 102, the second connector 106, and the set of support members 110: the first pin 140 extends into the first hole 160 to removably couple the second connector 106 to the first connector 102 and the second pin 190 extends into the second hole 180 to removably couple the second connector 106 to the first support member 114 such that the second connector 106 is movable relative to the first connector 102 and the first support member 114 and complementary connectors of the at least one electronic module inserted into the at least one bay 151-1 are engageable with the first and second connectors 102, 106.

In some other examples, the third connector 106A is selected from the modular connector system 100 and removably coupled to the first connector 102 to form a second connector assembly 1000-2. In particular, the third support wall 150A of the third connector 106A is placed adjacent to the first support wall 130 of the first connector 102 such that the first pin 140 of the first connector 102 protrudes at least partially into the first hole 160A of the third connector 106A to removably couple the third connector 106A to the first connector 102. Further, the front face 188 of the first support member 114 is disposed adjacent to the fourth support wall 152A of the third connector 106A such that the second pin 190 of the first support member 114 protrudes into the second hole 180A of the third connector 106A to removably couple the third connector 106A to the first support member 114. Since the first diameter “D₃” of the second hole 180A is greater than the second diameter “D₄” of the second pin 190, the third connector 106A is allowed to move along the first direction 10 relative to the first connector 102, which allows the third connector 106A to be aligned with the electronic module in view of tolerance stack up. In other words, the first and second holes 160A, 180A allow the third connector 106A to move along the first direction 10 relative to the first and second pins 140, 190. The second support member 114A is disposed spaced apart from the first support member 114 such that a front face of the first end 184A of the second support member 114A contacts the second support wall 132. Further, the third support member 114B is disposed between the first support member 114 and the second support member 114A such that a front face of the first end 184B of the third support member 114B contacts the first and third support walls 132, 150A and defines a first bay 151-1A between the first and third support members 114, 114B and the third connector 106A, and a second bay 151-1B between the third and second support members 114B, 114A and the first connector 102. Further, each of the first, second, and third support members 114, 114A, 114B may be coupled to the chassis. In particular, a plurality of fasteners 191 may extend into the plurality of first fastener holes 179 in the first support member 114, and into a plurality of first holes (not shown) in the chassis to couple the first support member 114 to the chassis. Similarly, a plurality of second fasteners 191A may extend into the plurality of second fastener holes 179A in the second support member 114A and into a plurality of second holes (not shown) in the chassis to couple the second support member 114A to the chassis. Further, a plurality of third fasteners 191B may extend into the plurality of third fastener holes 179B in the third support member 114B and into a plurality of third holes (not shown) in the chassis to couple the third support member 114B to the chassis. In some examples, a second electronic module having a small form factor is insertable into the first bay 151-1A to detachably couple with the third connector 106A and to electrically connect the second electronic module to the primary system board via the third connector 106A. For example, the second electronic module may slidingly engage with the first and third guide rails 176, 176B to move inside the first bay 151-1A and detachably couple with the third connector 106A. Similarly, a third electronic module having a small form factor is insertable into the second bay 151-1B to detachably couple with the first connector 102 and to electrically connect the third electronic module to the primary system board via the first connector 102. For example, the third electronic module may slidingly engage with the fourth and second guide rails 176C, 176A to move inside the second bay 151-1B and detachably couple with the first connector 102.

In some examples, the first side 136 of the first connector 102 is configured to mount to an edge of the first edge connector (not shown) in the primary system board. More particularly, the set of first contacts 146 at the first side 136 of the first connector 102 may be configured to clasp onto the edge of the first edge connector and electrically connect with the first edge connector of the primary system board. Further, the first receptacle 144 at the second side 138 of the first connector 102 is configured to receive a complementary connector e.g., a second edge connector of the third electronic module. More particularly, the set of second contacts 148 at the second side 138 of the first connector 102 may be configured to clasp onto the second edge connector of the third electronic module and electrically connect with the second edge connector of the third electronic module.

Further, the first side 156A of the third connector 106A is coupled to the second cable member 120A. For example, the PCB 123A is coupled to the cable 121A at the second surface connector 125A and the fourth edge connector 127 of the PCB 123A is electrically connected to the set of third contacts 166A at the first side 156A of the third connector 106A. More particularly, the set of third contacts 166A of the third connector 106A may be configured to clasp onto the fourth edge connector 127 of the PCB 123A and electrically connect the cable 121A with the first surface connector 122A. In such examples, the first surface connector 122A may be configured to further mount to another surface mount connector of the printed system board. Further, the second receptacle 164A at the second side 158A of the third connector 106A is configured to receive the third edge connector of the second electronic module. More particularly, the set of fourth contacts 168A at the second side 158A of the third connector 106A may be configured to clasp onto the third edge connector of the second electronic module and electrically connect with the third edge connector of the second electronic module.

In some examples, the first connector 102 may be coupled to the printed system board by extending a plurality of first fasteners 197 through the plurality of first mounting holes 126 in the first connector 102. Similarly, the third connector 106A may be coupled to the PCB 123A, after the second electronic module is clasped to the third connector 106A by extending a plurality of second fasteners 199A through the plurality of second mounting holes 172A in the third connector 106A.

Accordingly, in some other examples in an installed state of the first connector 102, the third connector 106A, and the set of support members 110: the first pin 140 extends into the third hole 160A to removably couple the third connector 106A to the first connector 102, and the second pin 190 extends into the fourth hole 180A to removably couple the third connector 106A to the first support member 114 such that the third connector 106A is movable relative to the first connector 102 and the first support member 114 and complementary connectors of the at least one electronic module inserted into the at least one bay 151-1A, 151-1B are engageable with the first and third connectors 102, 106A.

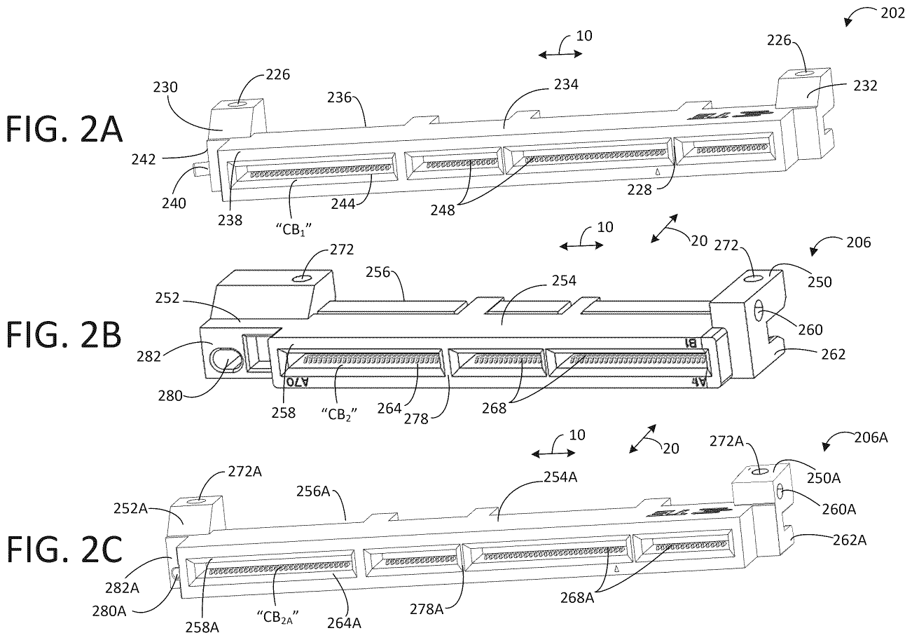

FIG. 2A depicts a perspective view of a first connector 202. In some examples, the first connector 202 includes a conductor component that may be configured to create an electrical connection between two electronic components. The first connector 202 includes a first support wall 230, a second support wall 232, and a first hollow body portion 234 defined between a first side 236 and a second side 238 of the first connector 202. The first connector 202 further includes a first pin 240 protruding from a side face 242 of the first support wall 230 and extending along a first direction 10. Further, the first connector 202 includes a set of first contacts (not shown) on the first side 236 and a first receptacle 244 at the second side 238, where the first receptacle 244 includes a set of second contacts 248. Further, the first connector 202 includes a plurality of first mounting holes 226 disposed on the first support wall 230 and the second support wall 232. In some examples, the first connector 202 may have a first profile. For example, the first profile of the first connector 202 is defined by a four number of connector bays “CB₁” separated from each other by three support elements 228. Further, the first connector 202 has a first width extending along the first direction “10”. In some examples, the first connector 202 is a 4C+ connector.

FIG. 2B depicts a perspective view of a second connector 206. In some examples, the second connector 206 includes a conductor component that may be configured to create an electrical connection between two electronic components. In some examples, the second connector 206 includes a third support wall 250, a fourth support wall 252, and a second hollow body portion 254 defined between a first side 256 and a second side 258 of the second connector 206. The second connector 206 further includes a first hole 260 formed at a side face 262 of the third support wall 250, and a second hole 280 formed at a rear face 282 of the fourth support wall 252. The first hole 260 extends inwards along the first direction 10 in the third support wall 250 and the second hole 280 extends inwards along a second direction 20 opposite to the first direction 10, in the fourth support wall 252. In some examples, the first pin 240 of the first connector 202 may be configured to protrude at least partially into the first hole 260 to removably couple the second connector 206 to the first connector 202. Further, the second connector 206 includes a set of third contacts (not shown) on the first side 256 and a second receptacle 264 at the second side 258, where the second receptacle 264 includes a set of fourth contacts 268. Further, the second connector 206 includes a plurality of second mounting holes 272 disposed on the third support wall 250 and the fourth support wall 252. In some examples the second connector 206 may have a second profile. For example, the second profile of the second connector 206 is defined by a three number of connector bays “CB₂” separated from each other by two support elements 278. In some examples, the second connector 206 is a 4C connector.

FIG. 2C depicts a perspective view of a third connector 206A. In some examples, the third connector 206A includes a conductor component that may be configured to create an electrical connection between two electronic components. In some examples, the third connector 206A includes a third support wall 250A, a fourth support wall 252A, and a second hollow body portion 254A defined between a first side 256A and a second side 258A of the third connector 206A. The third connector 206A further includes a first hole 260A (or a third hole) formed at a side face 262A of the third support wall 250A and a second hole 280A (or a fourth hole) formed at a rear face 282A of the fourth support wall 252A. The first hole 260A extends inwards along the first direction 10 in the third support wall 250A and the second hole 280A extends inwards along a second direction 20 in the fourth support wall 252A. In some examples, the first pin 240 of the first connector 202 may be configured to protrude at least partially into the first hole 260A to removably couple the third connector 206A to the first connector 202. Further, the third connector 206A includes a set of third contacts (not shown) on the first side 256A and a second receptacle 264A at the second side 258A, where the second receptacle 264A includes a set of fourth contacts 268A. Further, the third connector 206A includes a plurality of second mounting holes 272A disposed on the third support wall 250A and the fourth support wall 252A. In some examples the third connector 206A may have a third profile. For example, the third profile of the third connector 206A is defined by a four number of connector bays “CB_{2A}” separated from each other by three support elements 278A. It may be noted herein that the third profile may be substantially similar to the first profile of the first connector 202. In particular, the first hollow body portion 234 of the first connector 202 is similar to the second hollow body portion 254A of the third connector 206A. Further, the third and fourth support walls 250, 252 of the second connector 206 are similar to the third and fourth support walls 250A, 252B of the third connector 206. In some examples, the third connector 206A is a 4C+ connector.

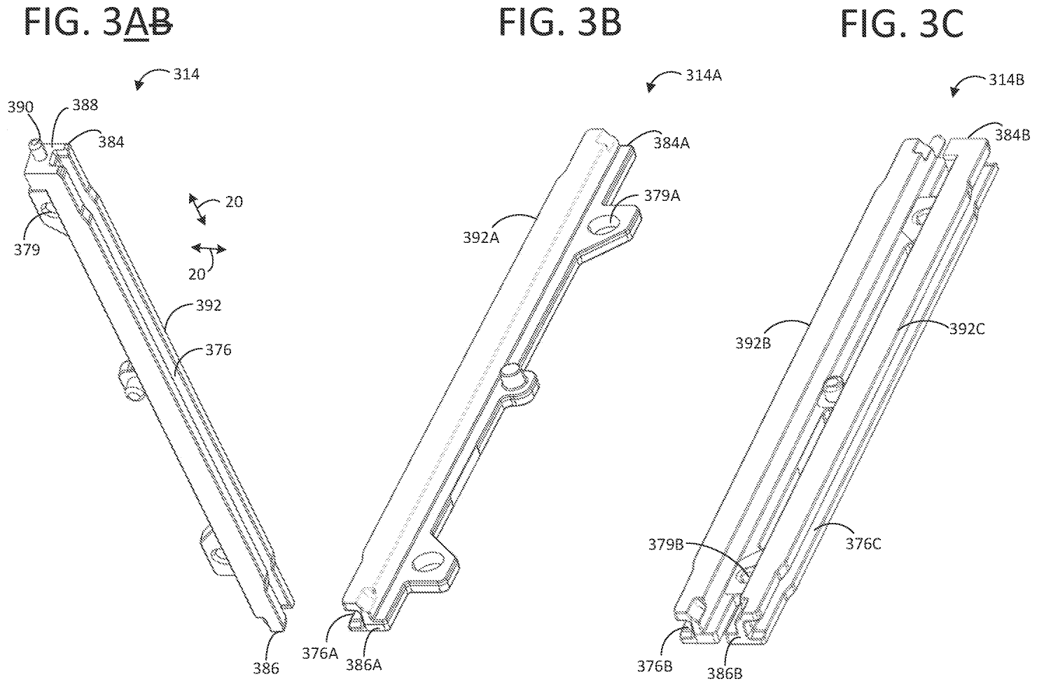

FIG. 3A depicts a perspective view of a first support member 314. The first support member 314 may be coupled to a chassis (not shown) and to the second connector 206 or the third connector 206A of the electronic device to define at least one bay (not shown) for receiving at least one electronic module (not shown). The first support member 314 includes a front face 388 defined at a first end 384 of the first support member 314 and a second pin 390 protruding outwards from the front face 388. The second pin 390 extends along a second direction 20 perpendicular to the first direction 10. The second pin 390 may protrude into one of the second holes 280, 280A to removably couple to a second connector 206 or a third connector 206A to the first support member 314. The second pin 390 has a second diameter smaller than a first diameter of the second hole 280 in the second connector 206. Similarly, the second diameter of the second pin 390 is also smaller than a first diameter of the second hole 280A in the third connector 206A. In some examples, the second pin 390 having the second diameter smaller than the first diameter of the first hole 260 may allow the second connector 206 to move along the first direction 10. Similarly, the second pin 390 having the second diameter smaller than the first diameter of the first hole 260 may allow the third connector 206 to move along the first direction 10. The first support member 314 includes a first guide rail 376 formed between the first and second ends 384, 386, and a plurality of first fastener holes 379. In some examples, the first guide rail 176 is defined along an inner side 392 of the first support member 314.

FIG. 3B depicts a perspective view of a second support member 314A. The second support member 314A may be coupled to a chassis to define at least one bay (not shown) for receiving at least one electronic module (not shown). The second support member 314A includes a first end 384A and a second end 386A, a second guide rail 376A formed between the first and second ends 384A, 386A, and a plurality of second fastener holes 379A. In some examples, the second guide rail 376A is formed along an inner side 392A of the second support member 314A.

FIG. 3B depicts a perspective view of a third support member 314B. The third support member 314B may be disposed between the first and second support members 314, 314A, coupled to a chassis to define at least two bays (not shown) therebetween for receiving at least one electronic module (not shown). The third support member 314B includes a first end 384B and a second end 386B. The third support member 314B further includes a third guide rail 376B formed between the first and second ends 384A, 386A on a first side 392B of the third support member 314B, and a fourth guide rail 376C formed between the first and second ends 384A, 386A on a second side 392C opposite to the first side 392B of the third support member 314B. Further, the third support member 314B includes a plurality of third fastener holes 379B.

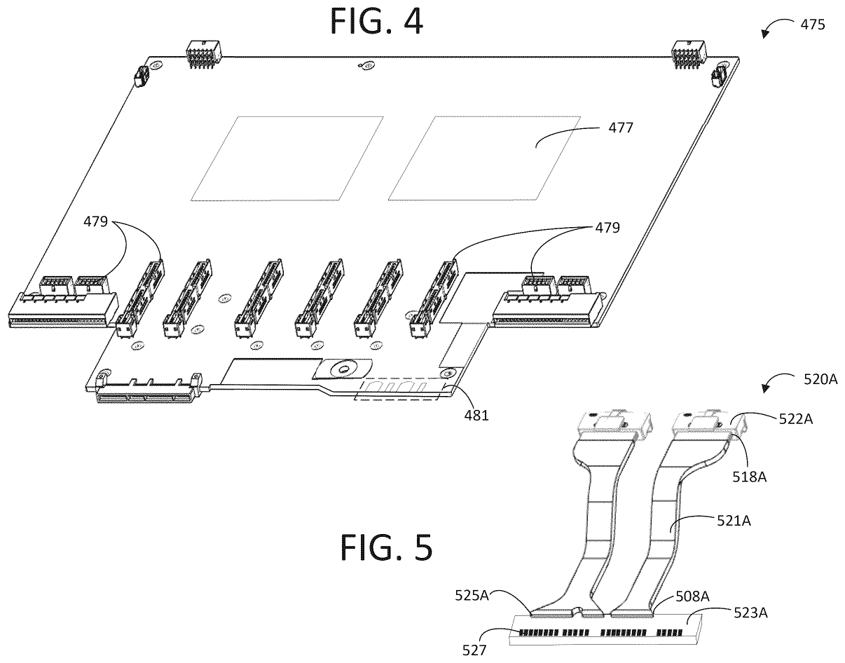

FIG. 4 depicts a perspective view of a primary system board 475 of an electronic device. The primary system board 475 is a motherboard or a host platform module of the electronic device. The primary system board 475 includes processing circuitry 477, a plurality of surface mount connectors 479, and a first edge connector 481. The processing circuitry 477 may be central processing unit, graphics processing unit, or the like. The processing circuitry 477 may be electrically coupled to the one or more surface mount connectors 479 and the first edge connector 481.

FIG. 5 depicts a perspective view of one of a cable member e.g., a second cable member 520A from a set of cable assemblies. The second cable member 520A includes a cable 521A, a printed circuit board (PCB 523A), a first surface connector 522A, and a second surface connector 525A. In the example of FIG. 5, two cables 521A are shown. The cable 521A includes a first end 508A and a second end 518A. The first end 508A of the cable 521A is coupled to the second surface connector 525A and the second end 518A of the cable 521A is coupled to the first surface connector 522A. In such examples, the second surface connector 525A is mounted to a second end (not labeled) of the PCB 523A. Further, the PCB 523A includes a fourth edge connector 527 disposed at a first end (not labeled) of the PCB 523A.

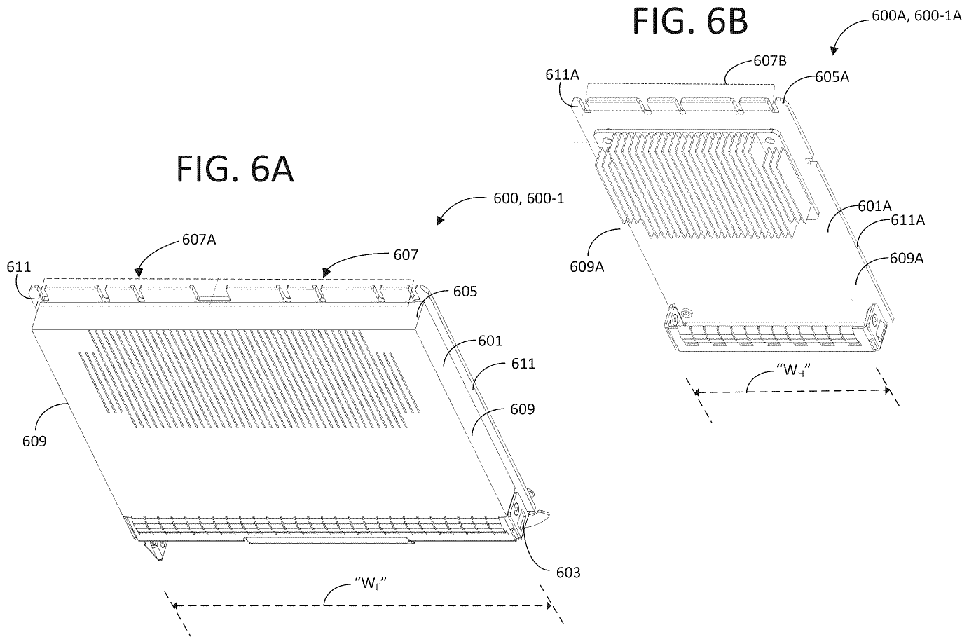

FIG. 6A depicts a perspective view of a first electronic module 600. In some examples, the first electronic module 600 is an open compute program (OCP) module 600-1. In such examples, the OCP module may be a modular network module having multiple network interface ports that can be configured to support various networking protocols such as Ethernet, Modbus TCP, PROFINET, IEC 61850, or the like. The first electronic module 600 has a large form factor. The first electronic module 600 includes an enclosure 601 having a plurality of electronic components (not shown) disposed therein, a front panel 603, a rear panel 605, and sidewalls 609 connecting the front and rear panels 603, 605. The front panel 603 may include network interface ports (not shown) electrically connected to the plurality of electronic components, and the rear panel 605 has a second edge connector 607 (or second complementary connector) and a third edge connector 607A (or third complementary connector), each electrically connected to the plurality of electronic components. In one or more examples, the second and third edge connectors 607, 607A may collectively be referred to as complementary connectors. In such examples, the second edge connector 607 has a first complementary profile that is commensurate with a first profile of the first connector 202 (see, FIG. 2A). Similarly, the third edge connector 607A has a second complementary profile that is commensurate with a second profile of the third connector 206A (see, FIG. 2B). Further, the first electronic module 600 has a full width “W_{F}”, which may be equal to a total width of the first and second connectors 202, 206A. In one or more examples, each of the sidewalls 609 of the first electronic module 600 includes a third guide rail 611.

FIG. 6B depicts a perspective view of a second electronic module 600A. In some examples, the second electronic module 600A is an open compute program (OCP) module 600-1A. The second electronic module 600A has a small form factor. The second electronic module 600A includes an enclosure 601A having a plurality of electronic components (not shown) disposed therein, a front panel 603A, a rear panel 605A, and sidewalls 609A connecting the front and rear panels 603A, 605A. The front panel 603A may include network interface ports (not shown) electrically connected to the plurality of electronic components, and the rear panel 605A has a fifth edge connector 607B (also referred to as third edge connector of the second electronic module 600A) electrically connected to the plurality of electronic components. In such examples, the fifth edge connector 607B has a third complementary profile that is commensurate with a third profile of the third connector 206A (see, FIG. 2C). In other words, the third complementary profile of the fifth edge connector 607B is substantially similar to the first complementary profile of the second edge connector 607. The second electronic module 600A has a half width “W_{H}”, which may be equal to a width of the first or third connectors 202, 206A. In one or more examples, each of the sidewalls 609A of the second electronic module 600A includes a fifth guide rail 611A.

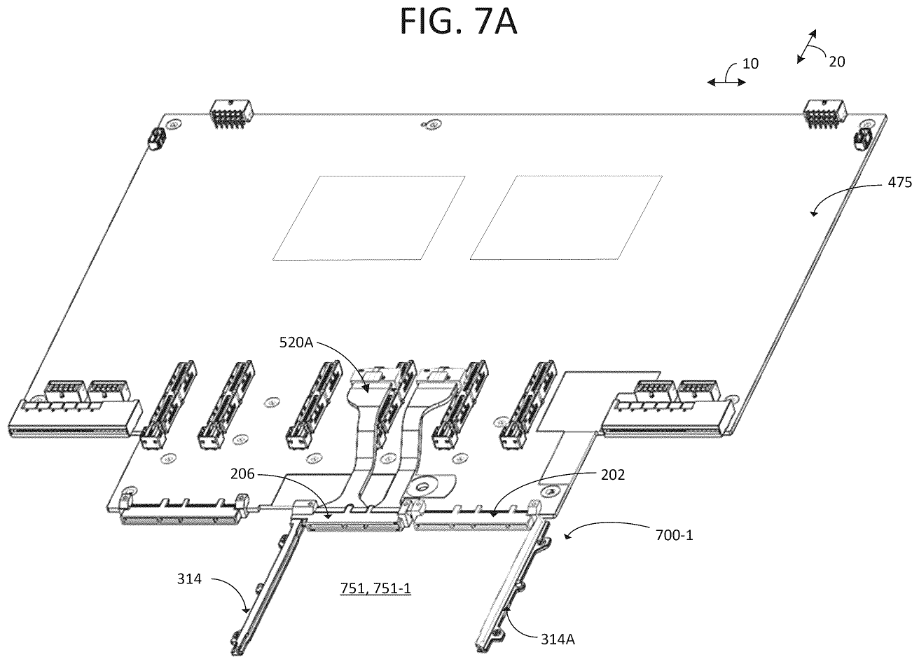

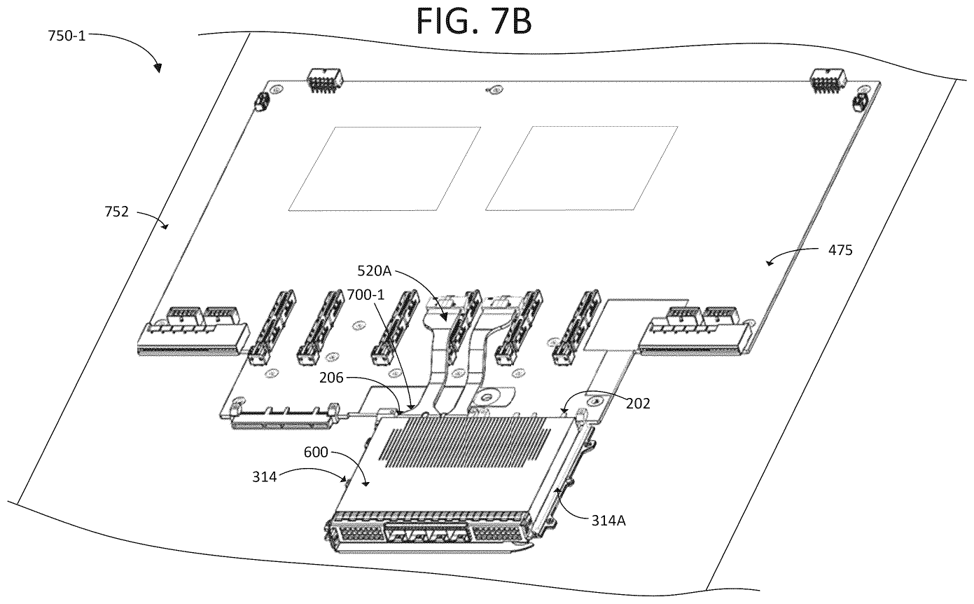

FIG. 7A depicts a perspective view of the primary system board 475 of FIG. 4 connected to a first connector assembly 700-1 having the first connector 202 of FIG. 2A, the second connector 206 of FIG. 2B, a second cable member 520A of FIG. 5, the first support member 314 of FIG. 3A, and the second support member 314A of FIG. 3B. It may be noted herein that FIG. 7A is discussed below referring to FIGS. 2A-2B, 3A-3B, and 4-5.

In some examples, the first side 236 of the first connector 202 is mounted to an edge of the first edge connector 481 in the primary system board 475. More particularly, the set of first contacts of the first connector 202 clasps onto the edge of the first edge connector 481 to electrically connect the first connector 202 to the primary system board 475. Further, the first side 256 of the second connector 206 is coupled to the second cable member 520A. For example, the PCB 523A is coupled to the second connector 206. More particularly, the set of third contacts 266 of the second connector 206 clasps onto the fourth edge connector 527 of the PCB 523A to electrically connect the PCB 523A to the first surface connector 522A via the second surface connector 525A and the cable 521A. In such examples, the first surface connector 522A is further mounted to a surface mount connector 479 of the primary system board 475 so as to electrically connect the second connector 206 to the primary system board 475.

Further, the second connector 206 is removably coupled to the first connector 202 to form the first connector assembly 700-1. In particular, the third support wall 250 of the second connector 206 is placed adjacent to the first support wall 230 of the first connector 202 such that the first pin 240 of the first connector 202 protrudes at least partially into the first hole 260 of the second connector 206 to removably couple the second connector 206 to the first connector 202. Further, the front face 388 of the first support member 314 is disposed adjacent to the fourth support wall 252 of the second connector 206 such that the second pin 390 of the first support member 314 protrudes into the second hole 280 of the second connector 206 to removably couple the second connector 206 to the first support member 314. Since the first diameter of the second hole 280 is greater than the second diameter of the second pin 390, the second connector 206 is allowed to move along the first direction 10 relative to the first connector 202. In other words, the first and second holes 260, 280 allow the second connector 206 to move along the first direction 10 relative to the first and second pins 240, 390.

In some examples, the first connector 202 may be coupled to the printed system board by extending a plurality of first fasteners (not shown) through the plurality of first mounting holes 226 in the first connector 202. Similarly, the second connector 206 may be coupled to the PCB 523A. Further, the second support member 314A is disposed spaced apart from the first support member 314 such that a front face of the first end 384A in the second support member 314A contacts the second support wall 232 of the first connector 202 and defines at least one bay 751 e.g., a first bay 751-1 between the first and second support members 314, 314A and the first and second connectors 202, 206.

FIG. 7B depicts a perspective view of an electronic device 750-1 having a chassis 752, the primary system board 475 of FIG. 4 electrically connected to a first electronic module 600 of FIG. 6A via the first connector assembly 700-1 of FIG. 7A. The first electronic module 600 is inserted into the first bay 751-1 such that the third guide rails 611 of the first electronic module 600 slidingly engage with the first guide rail 376 of the first support member 314 and the second guide rail 376A of the second support member 314A to guide the first electronic module 600 into first connector assembly 700-1 and removably couple the first electronic module 600 to the electronic device 750-1. In some examples, as the first electronic module 600 is inserted into the first bay 751-1, the first receptacle 244 of the first connector 202 receives a complementary connector e.g., a second edge connector 607 of the first electronic module 600 and the second receptacle 264 of the second connector 206 receives another complementary connector e.g., a third edge connector 607A of the first electronic module 600. More particularly, the set of second contacts 248 of the first connector 102 clasps onto the second edge connector 607 of the first electronic module 600 and the set of fourth contacts 268 of the second connector 206 clasps onto the third edge connector 607A of the first electronic module 600 to electrically connect the first electronic module 600 to the primary system board 475 via the first connector 202 and the second connector 206. Further, the first and second support members 314, 314A is coupled to a chassis 752 by protruding a plurality of first and second fasteners (not shown) into the plurality of first and second fastener holes 379, 379A in the first and second support members 314, 314A and into a plurality of first and second holes (not shown) in the chassis 752. Since the second connector 206 is not fixedly attached directly to the primary system board 475, and instead secured in place with the first connector 206 and the first support member 314 by pinned connections i.e., the first pin 240 and the second pin 390, it allows the second connector 206 to float or move within a limited range relative to the first connector 202 and align with the first electronic module 600 in view of tolerance stack up.

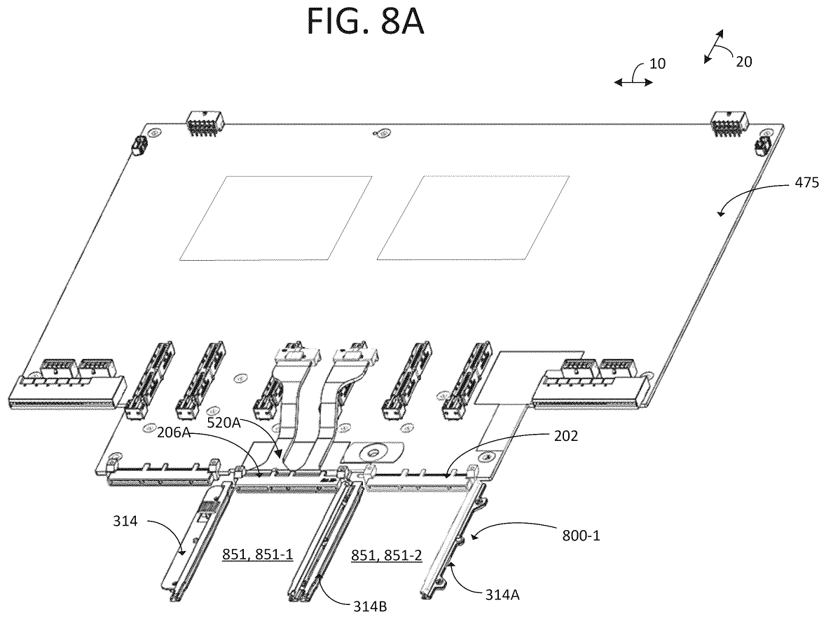

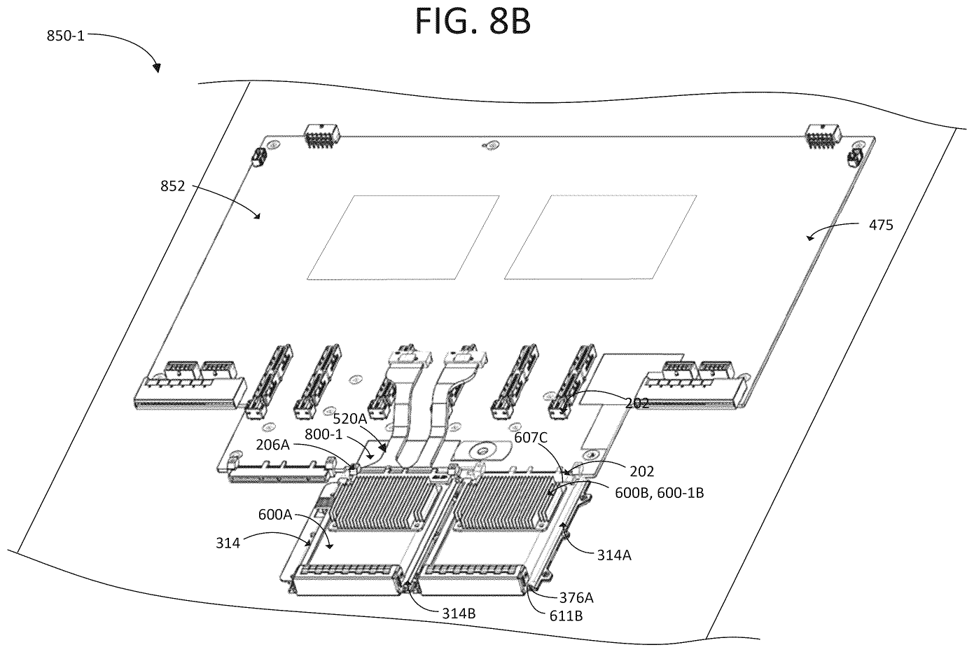

FIG. 8A depicts a perspective view of the primary system board 475 of FIG. 4 connected to a second connector assembly 800-1 having the first connector 202 of FIG. 2A, the third connector 206A of FIG. 2B, a second cable member 520A of FIG. 5, the first support member 314 of FIG. 3A, the second support member 314A of FIG. 3B, and the third support member 314B of FIG. 3C. It may be noted herein that FIG. 8A is discussed below referring to FIGS. 2A-2B, 3A-3C, and 4-5.

In some examples, the first side 236 of the first connector 202 is mounted to an edge of the first edge connector 481 in the primary system board 475. More particularly, the set of first contacts of the first connector 202 clasps onto the edge of the first edge connector 481 to electrically connect the first connector 202 to the primary system board 475. Further, the first side 256A of the third connector 206A is coupled to the second cable member 520A. For example, the PCB 523A is coupled to the third connector 206A. More particularly, the set of third contacts 266A of the third connector 206A clasps onto the fourth edge connector 527 of the PCB 523A to electrically connect the PCB 523A to the first surface connector 522A via the second surface connector 525A and the cable 521A. In such examples, the first surface connector 522A is further mounted to a surface mount connector 479 of the primary system board 475 so as to electrically connect the third connector 206A to the primary system board 475.

Further, the third connector 206A is removably coupled to the first connector 202 to form the second connector assembly 700-2. In particular, the third support wall 250A of the third connector 206A is placed adjacent to the first support wall 230 of the first connector 202 such that the first pin 240 of the first connector 202 protrudes at least partially into the first hole 260A of the third connector 206A to removably couple the third connector 206A to the first connector 202. Further, the front face 388 of the first support member 314 is disposed adjacent to the fourth support wall 252A of the third connector 206A such that the second pin 390 of the first support member 314 protrudes into the second hole 280A of the third connector 206A to removably couple the third connector 206A to the first support member 314. Since the first diameter of the second hole 280A is greater than the second diameter of the second pin 390, the third connector 206A is allowed to move along the first direction 10 relative to the first connector 202. In other words, the first and second holes 260A, 280A allow the third connector 206A to move along the first direction 10 relative to the first and second pins 240, 390.

In some examples, the first connector 202 may be coupled to the printed system board by extending a plurality of first fasteners (not shown) through the plurality of first mounting holes 226 in the first connector 202. Similarly, the third connector 206A may be coupled to the PCB 523A. Further, the second support member 314A is disposed spaced apart from the first support member 314 such that a front face of the first end 384A in the second support member 314A contacts the second support wall 232 of the first connector 202. Similarly, the third support member 314B is disposed between the first and second support members 314, 314A such that a front face of the first end 384B in the third support member 314B contacts the first and third support walls 230, 250 of the first and second connectors 202, 206A respectively, and defines at least one bay 851 e.g., a second bay 851-1 between the first and third support members 314, 314B and third connector 206A and a third bay 851-2 between the third and second support members 314B, 314A and first connector 202.

FIG. 8B depicts a perspective view of an electronic device 850-1 having a chassis 852, the primary system board 475 of FIG. 4 electrically connected to a second electronic module 600A of FIG. 6A and a third electronic module 600B via the second connector assembly 700-2 of FIG. 7A. In some examples, the third electronic module 600B is an open compute program (OCP) module 600-1B. In such examples, the third electronic module 600B is similar to the second electronic module 600A. Therefore, the third electronic module 600B is not discussed in detail here and such non-description of the third electronic module 600B should not be construed as a limitation of the present disclosure.

The second electronic module 600A is inserted into the first bay 851-1 such that the fifth guide rails 611A of the second electronic module 600A slidingly engage with the first guide rail 376 of the first support member 314 and the third guide rail 376B of the third support member 314B to guide the second electronic module 600A into the second connector assembly 800-1 and removably couple the second electronic module 600A to the third connector 206A of the second connector assembly 800-1. Similarly, the third electronic module 600A is inserted into the second bay 851-2 such that the sixth guide rails 611B of the third electronic module 600B slidingly engage with the fourth guide rail 376C of the third support member 314B and the second guide rail 376A of the second support member 314A to guide the third electronic module 600B into the second connector assembly 800-1 and removably couple the third electronic module 600B to the first connector 202 of the second connector assembly 800-1. In some examples, as the second electronic module 600A is inserted into the first bay 851-1, the second receptacle 264A of the third connector 206A receives a complementary connector e.g., a fifth edge connector 607B of the second electronic module 600A such that the set of fourth contacts 268A of the third connector 206A clasps onto the fifth edge connector 607B of the second electronic module 600A to electrically connect the second electronic module 600A to the primary system board 475 via the third connector 206A. Similarly, as the third electronic module 600B is inserted into the second bay 851-2, the first receptacle 244 of the first connector 202 receives a complementary connector e.g., a third edge connector 607C of the third electronic module 600B such that the set of second contacts 248 of the first connector 202 clasps onto the third edge connector 607C of the third electronic module 600B to electrically connect the third electronic module 600B to the primary system board 475 via the first connector 202. Further, the first, second, and third support members 314, 314A, 314B are coupled to the chassis 852 by protruding a plurality of first, second, and third fasteners (not shown) into the plurality of first, second, and third fastener holes 379, 379A, 379B in the first, second, and third support members 314, 314A, 314B and into a plurality of first, second, and third holes (not shown) in the chassis 852. Since the third connector 206A is not fixedly attached directly to the primary system board 475, and instead secured in place with the first connector 206 and the first support member 314 by pinned connections i.e., the first pin 240 and the second pin 390, it allows the third connector 206A to float or move within a limited range relative to the first connector 202 and align with the second electronic module 600A in view of tolerance stack up.

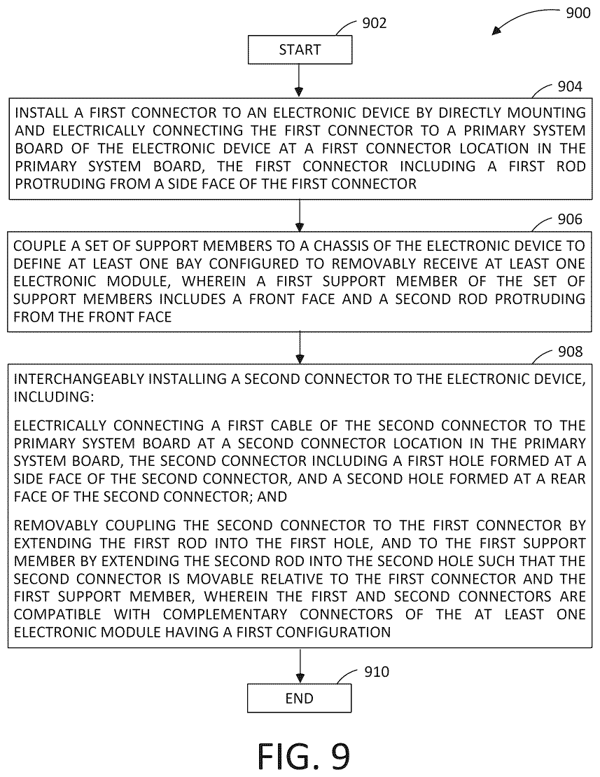

FIG. 9 depicts a flowchart showing a method 900 of installing a connector assembly to a primary system board of an electronic device. It may be noted herein that the method 900 is described in conjunction with FIGS. 2A-2C, 3A-3C, 4-5, 61-6B, 7A-7B, and 8A-8B for example. The method 900 starts at block 902 and continues to block 904.

At block 904, the method 900 includes installing a first connector to the electronic device by directly mounting and electrically connecting the first connector to a primary system board of the electronic device at a first connector location in the primary system board, the first connector including a first rod protruding from a side face of the first connector. The method 900 continues to block 906.

At block 906, the method 900 includes coupling a set of support members to a chassis of the electronic device to define at least one bay configured to removably receive at least one electronic module, where a first support member of the set of support members includes a front face and a second rod protruding from the front face. The method 900 continues to block 908.

At block 908, the method 900 includes interchangeably installing a second connector to the electronic device. In some examples, the interchangeably installing the second connectors includes i) electrically connecting a first cable of the second connector to the primary system board at a second connector location in the primary system board, the second connector including a first hole formed at a side face of the second connector, and a second hole formed at a rear face of the second connector, and ii) removably coupling the second connector to the first connector by extending the first rod into the first hole, and to the first support member by extending the second rod into the second hole such that the second connector is movable relative to the first connector and the first support member, wherein the first and second connectors are compatible with complementary connectors of the at least one electronic module having a first configuration.

In some examples, the method 900 further includes uninstalling the second connector from the electronic device by i) disconnecting the first cable at the second connector location from the primary system board, and ii) decoupling the second connector from the first support member by drawing out the second rod from the second hole, and the first connector by drawing out the first rod from the first hole.

The method 900 additionally includes installing a third connector to the electronic device by i) electrically connecting a second cable of the third connector to the primary system board at the second connector location, the third connector including a third hole formed at a side face of the third connector and a fourth hole formed at a rear face of the third connector and ii) removably coupling the third connector to the first connector by extending the first rod into the third hole, and to the first support member by extending the second rod into the fourth hole such that the third connector is movable relative to the first connector and the first support member, where the first and third connectors are compatible with complementary connectors of the at least one electronic module having a second configuration. The method 900 ends at block 910.

In the foregoing description, numerous details are set forth to provide an understanding of the subject matter disclosed herein. However, implementation may be practiced without some or all of these details. Other implementations may include modifications, combinations, and variations from the details discussed above. It is intended that the following claims cover such modifications and variations.

What is claimed is:

1. An electronic device, comprising:
a chassis;
a primary system board mounted to the chassis and comprising processing circuitry;
a first connector directly mounted and electrically connected to the primary system board, comprising a first support wall, a second support wall, and a first pin protruding from a side face of the first support wall and extending along a first direction;
a second connector comprising a cable electrically connected to the primary system board, a third support wall, a fourth support wall, a first hole formed at a side face of the third support wall, and a second hole formed at a rear face of the fourth support wall, wherein the first pin protrudes at least partially into the first hole to removably couple the second connector to the first connector; and
a set of support members coupled to the chassis and defining at least one bay, wherein a first support member of the set of support members comprises a front face and a second pin protruding from the front face and extending along a second direction perpendicular to the first direction, and wherein the second pin protrudes into the second hole to removably couple the second connector to the first support member,
wherein at least one electronic module is insertable into the at least one bay to detachably couple with at least one of the first and second connectors to electrically connect the at least one electronic module to the primary system board via the first and second connectors, and
wherein the first and second holes allow the second connector to move along the first direction relative to the first and second pins.

2. The electronic device of claim 1, wherein the second hole has a first diameter, and wherein the second pin has a second diameter smaller than the first diameter to allow the second connector to move along the first direction.

3. The electronic device of claim 1, wherein the set of support members further comprises a second support member disposed spaced apart from the first support member to define a first bay of the at least one bay, and wherein the at least one electronic module comprises an open compute program (OCP) module having a large form factor that is insertable into the first bay such that the OCP module is engaged with and supported by the first and second support members and a first complementary connector and a second complementary connector of the OCP module is detachably coupled to the first connector and the second connector, respectively.

4. The electronic device of claim 3, wherein the first support member comprises a first guide rail, the second support member comprises a second guide rail, wherein each sidewall of the OCP module comprises a third guide rail, and wherein, as the OCP module is inserted into the first bay, the third guide rails slidingly engage with the first and second guide rails to guide the OCP module into the first bay and to removably couple the OCP module to the electronic device.

5. The electronic device of claim 1, wherein the set of support members further comprises a second support member and third support member, where each of the first, second, and third support members are disposed spaced apart from each other to define a first bay and a second bay of the at least one bay, wherein the at least one electronic module comprises a first open compute program (OCP) module and a second OCP module, each having a small form factor, and wherein the first OCP module and the second OCP module are insertable into the first bay and second bay, respectively, such that a first complementary connector of the first OCP module is detachably coupled to the first connector and a second complementary connector of the second OCP module is detachably coupled to the second connector.

6. The electronic device of claim 5, wherein the first support member comprises a first guide rail, the second support member comprises a second guide rail, and the third support member comprises a third guide rail and a fourth guide rail, each formed on a corresponding side of the third support member, wherein each sidewall of the first OCP module comprises a fifth guide rail and each sidewall of the second OCP module comprises a sixth guide rail, and wherein, as the first OCP module is inserted into the first bay, the fifth guide rails engage with the first and third guide rails to guide the first OCP module into the first bay and to removably couple the first OCP module to the electronic device, and wherein, as the second OCP module is inserted into the second bay, the sixth guide rails engage with the second and fourth guide rails to guide the second OCP module into the second bay and to removably couple the second OCP module to the electronic device.

7. The electronic device of claim 1,
wherein the primary system board comprises a first edge connector electrically connected to the first connector and a surface mount connector electrically connected to the cable;
wherein a first side of the first connector is mounted to an edge of the primary system board at the first edge connector and a second side of the first connector comprises a first receptacle configured to receive a second edge connector of one of the at least one electronic module; and
wherein a first side of the second connector is coupled to the cable and a second side of the second connector comprises a second receptacle configured to receive a third edge connector of one of the at least one electronic module.

8. The electronic device of claim 7,
wherein the first connector comprises a set of first contacts on the first side of the first connector electrically connected to the first edge connector and a set of second contacts disposed in the first receptacle to electrically connect with the second edge connector; and
wherein the second connector comprises a PCB comprising a fourth edge connector electrically coupled to the cable, a set of third contacts on the first side of the second connector electrically connected to the fourth edge connector, and a set of fourth contacts disposed in the second receptacle to electrically connect with the third edge connector.

9. The electronic device of claim 7,
wherein the first connector comprises a set of first contacts on the first side of the first connector electrically connected to the first edge connector and a set of second contacts disposed in the first receptacle to electrically connect with the second edge connector; and
wherein the second connector comprises a set of third contacts on the first side of the second connector soldered to the cable and a set of fourth contacts disposed in the second receptacle to electrically connect with the third edge connector.

10. A modular connector system for an electronic device, comprising:
a first connector configured to directly mount and electrically connect to a primary system board of the electronic device, the first connector comprising a first pin protruding from a side face of the first connector;
a second connector comprising a first cable configured to be electrically connected to the primary system board, a first hole formed at a side face of the second connector, and a second hole formed at a rear face of the second connector;
a third connector comprising a second cable configured to electrically connect to the primary system board, a third hole formed at a side face of the third connector, and a fourth hole formed at a rear face of the third connector; and
a set of support members configured to be coupled to a chassis of the electronic device to define at least one bay configured to removably receive at least one electronic module, wherein a first support member of the set of support members comprises a front face and a second pin protruding from the front face,
wherein the first connector is installable in the electronic device at a first connector location and the second and third connectors are interchangeably installable in the electronic device at a second connector location,
wherein in an installed state of the first connector, the second connector, and the set of support members: the first pin extends into the first hole to removably couple the second connector to the first connector and the second pin extends into the second hole to removably couple the second connector to the first support member such that the second connector is movable relative to the first connector and the first support member and complementary connectors of the at least one electronic module inserted into the at least one bay are engageable with the first and second connectors,
wherein in an installed state of the first connector, the third connector, and the set of support members: the first pin extends into the third hole to removably couple the third connector to the first connector and the second pin extends into the fourth hole to removably couple the third connector to the first support member such that the third connector is movable relative to the first connector and the first support member and complementary connectors of the at least one electronic module inserted into the at least one bay are engageable with the first and third connectors.

11. The modular connector system of claim 10, wherein the second hole has a first diameter, wherein the second pin has a second diameter smaller than the first diameter to allow the second connector to move along a first direction relative to the first support member; and wherein the fourth hole has a third diameter greater than the second diameter of the second pin to allow the third connector to move along the first direction relative to the first support member.

12. The modular connector system of claim 10, wherein the set of support members further comprises a second support member disposed spaced apart from the first support member to define a first bay of the at least one bay, and wherein the at least one electronic module comprises an open compute program (OCP) module having a large form factor that is insertable into the first bay such that the OCP module is engaged with and supported by the first and second support members and a first complementary connector and a second complementary connector of the complementary connectors of the OCP module is detachably coupled to the first connector and the second connector, respectively.

13. The modular connector system of claim 12, wherein each of the first support member comprises a first guide rail, the second support member comprises a second guide rail, wherein each sidewall of the OCP module comprises a third guide rail, and wherein, as the OCP module is inserted into the first bay, the third guide rails slidingly engage with the first and second guide rails to guide the OCP module into the first bay and to removably couple the OCP module to the electronic device.

14. The modular connector system of claim 10, wherein the set of support members further comprises a second support member and third support member, where each of the first, second, and third support members are disposed spaced apart from each other to define a first bay and a second bay of the at least one bay, wherein the at least one electronic module comprises a first open compute program (OCP) module and a second OCP module, each having a small form factor, and wherein the first OCP module and the second OCP module are insertable into the first bay and second bay, respectively, such that a first complementary connector of the complementary connectors of the first OCP module is detachably coupled to the first connector and a second complementary connector of the complementary connectors of the second OCP module is detachably coupled to the third connector.

15. The modular connector system of claim 14, wherein the first support member comprises a first guide rail, the second support member comprises a second guide rail, and the third support member comprises a third guide rail and a fourth guide rail, each formed on a corresponding side of the second support member, wherein each sidewall of the first OCP module comprises a fifth guide rail and each sidewall of the second OCP module comprises a sixth guide rail, and wherein, as the first OCP module is inserted into the first bay, the fifth guide rails engage with the first and third guide rails to guide the first OCP module into the first bay and to removably couple the first OCP module to the electronic device, and wherein, as the second OCP module is inserted into the second bay, the sixth guide rails engage with the second and fourth guide rails to guide the second OCP module into the second bay and to removably couple the second OCP module to the electronic device.

16. The modular connector system of claim 10, wherein in the installed state of the first connector, the second connector, and the set of support members:
a first side of the first connector is mounted to an edge of the primary system board at a first edge connector and a second side of the first connector comprises a first receptacle configured to receive a second edge connector among the complementary connectors of a first electronic module of the at least one electronic module; and
a first side of the second connector is coupled to a surface mount connector of the primary system board via the first cable and a second side of the second connector comprises a second receptacle configured to receive a third edge connector among the complementary connectors of the first electronic module, and
wherein the first electronic module comprises an open compute program (OCP) module having a large form factor.

17. The modular connector system of claim 10, wherein in the installed state of the first connector, the third connector, and the set of support members,
a first side of the first connector is mounted to an edge connector of the primary system board at a first edge connector and a second side of the first connector comprises a first receptacle configured to receive a second edge connector among the complementary connectors of a first electronic module of the at least one electronic module; and
a first side of the third connector is coupled to a surface mount connector of the primary system board via the second cable and a second side of the third connector comprises a second receptacle configured to receive a third edge connector among the complementary connectors of a second electronic module of the at least one electronic module, and
wherein each of the first and second electronic modules comprises an open compute program (OCP) module having a small form factor.

18. A method comprising:
installing a first connector to an electronic device by directly mounting and electrically connecting the first connector to a primary system board of the electronic device at a first connector location in the primary system board, the first connector comprising a first pin protruding from a side face of the first connector;
coupling a set of support members to a chassis of the electronic device to define at least one bay configured to removably receive at least one electronic module, wherein a first support member of the set of support members comprises a front face and a second pin protruding from the front face; and
interchangeably installing a second connector to the electronic device, comprising:
electrically connecting a first cable of the second connector to the primary system board at a second connector location in the primary system board, the second connector comprising a first hole formed at a side face of the second connector, and a second hole formed at a rear face of the second connector; and
removably coupling the second connector to the first connector by extending the first pin into the first hole, and to the first support member by extending the second pin into the second hole such that the second connector is movable relative to the first connector and the first support member,
wherein the first and second connectors are compatible with complementary connectors of the at least one electronic module having a first configuration.

19. The method of claim 18, further comprising uninstalling the second connector from the electronic device by:
disconnecting the first cable at the second connector location from the primary system board; and
decoupling the second connector from the first support member by drawing out the second pin from the second hole, and the first connector by drawing out the first pin from the first hole.

20. The method of claim 19, further comprising installing a third connector to the electronic device, comprising:
electrically connecting a second cable of the third connector to the primary system board at the second connector location, the third connector comprising a third hole formed at a side face of the third connector and a fourth hole formed at a rear face of the third connector; and
removably coupling the third connector to the first connector by extending the first pin into the third hole, and to the first support member by extending the second pin into the fourth hole such that the third connector is movable relative to the first connector and the first support member,
wherein the first and third connectors are compatible with complementary connectors of the at least one electronic module having a second configuration.
